(19) United States
(12) Patent Application Publication
(10) Pub. No.: US 2010/0200063 A1
(43) Pub. Date: Aug. 12, 2010

(54) THIN FILM SOLAR CELL

(76) Inventor: Derek Djeu, San Francisco, CA (US)

Correspondence Address: BERKELEY LAW & TECHNOLOGY GROUP, LLP, 17933 NW Evergreen Parkway, Suite 250, BEAVERTON, OR, 97006, US

(21) Appl. No.: 12/370,575

(22) Filed: Feb. 12, 2009

(51) Int. Cl. H01L 31/0203; H01L 31/18

(52) U.S. Cl. 136/259; 438/64; 257/E31.117

(57) ABSTRACT

The subject matter disclosed herein relates to solar cell packaging. In one particular example, a solar cell package comprises a solar cell including a thin film solar cell disposed on a flexible and substantially transparent substrate, a first encapsulation layer disposed on a first side of the solar cell, and a second encapsulation layer disposed on a second side of the solar cell.

### RELATED APPLICATIONS

This is a PCT application claiming priority to U.S. Provisional Patent Application Nos. 60/958,294, filed on Jul. 5, 2007; 60/958,426, filed on Jul. 6, 2007; 60/966,689, filed on Aug. 30, 2007; 60/960,036, filed on Sep. 12, 2007; 60/960,547, filed on Oct. 3, 2007; and 61/008,310, filed on Dec. 20, 2007, which are incorporated herein by reference.

### BACKGROUND

1. Field

The subject matter disclosed herein relates to solar cell packaging.

2. Information

Continuing advances in semiconductor thin film solar cell technology make such solar cells an increasingly attractive alternative to traditional crystalline silicon solar cell modules. Thin film solar cells may use fewer raw materials and require less processing steps in their manufacture than their traditional counterparts.

Thin film solar cell modules may include a relatively thick sheet of glass to provide a rigid structure and protect thin film solar cell material from moisture and other elements. Since glass is highly transparent to sunlight, glass may provide environmental protection to semiconductor thin films without significantly reducing their efficiency. A thick sheet of glass covering a solar module tends to be heavy and dangerously breakable, rendering such solar modules difficult to handle and install in the field.

### BRIEF DESCRIPTION OF THE FIGURES

Non-limiting and non-exhaustive embodiments will be described with reference to the following figures, wherein like reference numerals refer to like parts throughout the various figures unless otherwise specified.

FIG. 1 is a cross-sectional view of a solar cell module, according to an embodiment.

FIG. 2 is a cross-sectional view of a solar cell module, according to another embodiment.

FIG. 3 is a cross-sectional view of a solar cell module, according to another embodiment.

FIG. 4 is a cross-sectional view of a solar cell module, according to another embodiment.

FIG. 5 is a cross-sectional view of a solar cell module, according to another embodiment.

FIG. 6 is a cross-sectional view of a solar cell module, according to another embodiment.

FIG. 7 is a cross-sectional view of a solar cell module, according to another embodiment.

FIG. 8 is a schematic view of a solar cell module array, according to an embodiment.

FIG. 9 is a schematic view of a process of manufacturing a solar cell module, according to an embodiment.

FIG. 10A is a top view and FIG. 10B is a cross-sectional view of a solar cell module, according to an embodiment.

FIG. 11A is a top view and FIG. 11B is a cross-sectional view of a lamination sheet, according to an embodiment.

FIGS. 12A and 12B are cross-sectional views of solar cell modules sandwiched between lamination layers, according to an embodiment.

FIGS. 13 and 14 are top views of two adjacent solar cell modules, according to an embodiment.

FIGS. 15A and 15B are schematic views of a solar module array including solar cell modules, according to an embodiment.

FIGS. 16A and 16B are schematic views of a solar module array including solar cell modules connected in parallel, according to an embodiment.

FIGS. 17A and 17B are schematic views of a substrate handler, according to an embodiment.

FIGS. 18A and 18B are schematic views of a substrate handler, according to another embodiment.

FIGS. 19A and 19B are schematic views of a substrate handler, according to another embodiment.

FIG. 20 is a perspective view of an embodiment of a cable and post mounting system.

FIG. 21A is a top view of a solar panel included in cable and post mounting structure, according to an embodiment.

FIG. 21B is a close-up view of an end region of a solar panel, according to an embodiment.

FIG. 22A is a top view of two interconnectable solar panels, according to an embodiment.

FIG. 22B is a detail view of two interconnectable solar panels, according to an embodiment.

FIG. 23 is a perspective view of an array of multiple cable and post mounting systems, according to an embodiment.

FIG. 24 is a perspective view of an installation of solar module arrays, according to an embodiment.

### DETAILED DESCRIPTION

In the following detailed description, numerous specific details are set forth to provide a thorough understanding of claimed subject matter. However, it will be understood by those skilled in the art that claimed subject matter may be practiced without these specific details. In other instances, well-known methods, procedures, components, and/or circuits have not been described in detail so as not to obscure claimed subject matter.

Reference throughout this specification to “one embodiment” or “an embodiment” means that a particular feature, structure, or characteristic described in connection with an embodiment is included in at least one embodiment of claimed subject matter. Thus, appearances of the phrase “in one embodiment” or “an embodiment” in various places throughout this specification are not necessarily all referring to the same embodiment. Furthermore, the particular features, structures, or characteristics may be combined in one or more embodiments.

In an embodiment, a solar cell package may include a thin film solar cell disposed on a flexible and substantially transparent substrate, such as an ultra-thin glass substrate. Though glass is mentioned as an example substrate in the presently illustrated embodiment, other materials may be used, and claimed subject matter is not limited in this respect. Such a flexible substrate, for example, may withstand substantial bending to conform with non-flat surfaces without breaking. In one particular implementation a flexible substrate may be capable of bending to less than a particular radius (e.g., to a radius of less than one meter) without breaking, for example. In such a configuration, a substantially transparent and flexible substrate may not only be used as a supporting structure during a deposition process of a thin film solar cell, but also as a window for solar cell illumination. In this respect, such a solar cell may be illuminated through the substrate, which may be advantageous to achieve relatively high operating efficiency for some solar cell materials, such as CdTe, for example. Here, a substantially transparent substrate permits light received on one surface to be transmitted through to solar cell materials formed on an opposite surface. Such would not be possible with other flexible substrates that are opaque (e.g., stainless steel). To provide further structural support as well as environmental protection to the thin film solar cell, an encapsulation layer, such as a polymer layer, for example, may be disposed on each of both sides of the solar cell-substrate combination. In this respect, one or more encapsulation layers may provide a hermetic seal not prone to delamination during bending of the solar cell. Adding such encapsulation layers may also increase durability of the thin film solar cell by spreading stresses more uniformly during bending. A particular implementation may involve an ultra-thin glass substrate that may be formed by fusing glass particles or powder, such as borosilicate. Such a forming process may allow a continuous ultra thin sheet of glass to run in a continuous fashion through a manufacturing line, as a deposition process forms a thin film solar cell. Another particular implementation may involve a glass substrate in the form of a sheet that is fabricated using a down draw process. In a particular implementation, a down draw process may involve pulling a continuous sheet of ultra thin glass from a body of molten glass downward through a slit, and then relatively quickly cooling the continuous sheet to solidify the glass. As mentioned above, other materials other than glass may be used, and claimed subject matter is not limited in this respect.

A solar cell module that is flexible and light weight, as may be the case for embodiments described herein, may be well-suited to be mounted on and physically conform to various structures such as curved glass on a roof, for example. Such flexibility facilitates handling and installation on a wide variety of surfaces. Encapsulation layers, which are described below, may also provide a hermetic seal that is not prone to delamination when such a solar cell module is bent and flexed, for example.

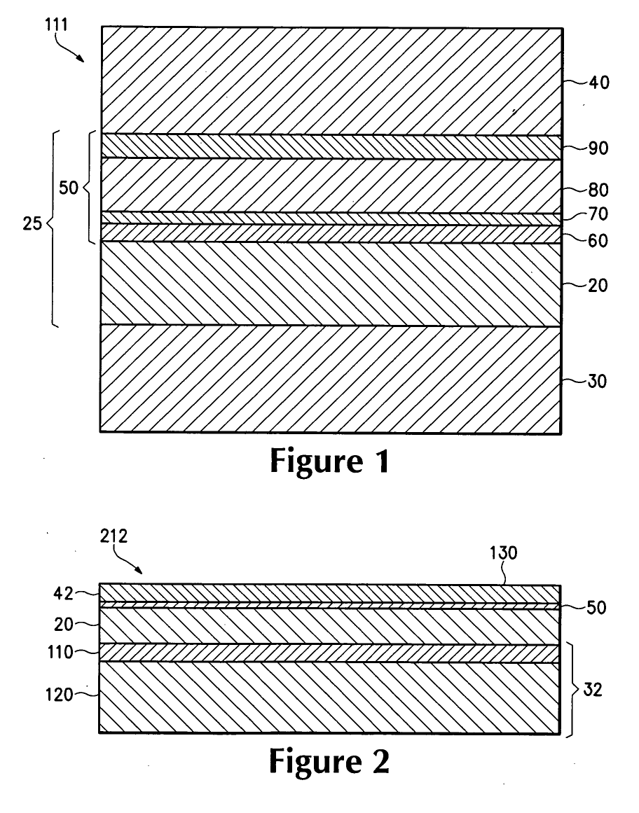

FIG. 1 is a cross-sectional view of a solar cell module 111, according to an embodiment. In a particular example, solar cell module 111 includes a solar cell 50 disposed on a substrate 20, which may be ultra-thin and flexible, such as ultra-thin glass, for example. Solar cell 50 may include a transparent conducting oxide (TCO) 60, such as SnO₂ or SnO₂:F, light absorbing semiconductor layers 70 and 80, and a conductive back contact 90, such as a metal. Semiconductor layers 70 and 80 may comprise materials such as CdS and CdTe, respectively. However, these are merely examples of light absorbing materials that may be used as a light absorbing layer of a thin film solar cell, and claimed subject matter is not limited in this respect. In one implementation, solar cell 50 may be about 10 micrometers thick, for example. Substrate 20 may comprise borosilicate, soda lime glass, glass under the brand name 0211 from Corning Inc., and/or glass under the brand names D 263 and AF45 from Schott Glass. However, these are merely examples of materials that may be used to form a flexible substrate according to a particular embodiment, and claimed subject matter is not limited in this respect. Substrate 20 may be less than 200 micrometers thick, for example to provide flexibility, which generally increases with decreasing thickness. Solar cell 50 and substrate 20 are herein collectively called a composite solar cell 25, though claimed subject matter is not limited to such language. Also, thicknesses of solar cell layers given in these embodiments are merely examples, and claimed subject matter is not so limited.

In one embodiment, composite solar cell 25 may be sandwiched between encapsulation layers, such as polymer layers, for example. In particular, as shown in FIG. 1, composite solar cell 25 may be disposed on a first encapsulation layer 30 and covered by a second encapsulation layer 40. Encapsulation layers 30 and 40 may include multiple layers of clear plastic or adhesive polymers such as ethyl vinyl acetate (EVA), a fluoropolymer such as ethyl tetra flouroethylene (ETFE), hard polymers such as Acrylic, PMMA, polyimide, and Mylar, and/or soft polymers such as Tefzel and Teflon. In a particular embodiment, such hard polymers may be applied to composite solar cell 25 by dipping, spraying, and/or spin coating, just to name a few examples. However, these are merely examples of materials and methods of applications that may be used to form laminated layers according to a particular embodiment, and claimed subject matter is not limited in this respect. In a particular implementation, first encapsulation layer 30 and second encapsulation layer 40 may comprise single layers with a thickness of about 250 micrometers.

In one embodiment, substrate 20 may comprise a glass sheet to provide a substrate to which solar cell 50 may be deposited. Such deposition may include close space sublimation (CSS), physical vapor deposition (PVD), chemical vapor deposition (CVD), electrochemical deposition (ECD), molecular beam epitaxy (MBE), and atomic layer deposition (ALD), for example. In an alternative embodiment, a pre-formed solar cell 50 may be laminated onto substrate 20. Such methods of combining a solar cell with a substrate described herein are only examples, and claimed subject matter is not so limited. In addition to providing a deposition or laminating surface for solar cell 50, substrate 20 may also provide such a surface for deposition of first and/or second encapsulation layers 30 and 40, according to a particular embodiment. Substrate 20 may be transparent to provide an illumination window for solar cell 50 during operation.

First and second encapsulation layers 30 and 40 may provide bulk structural support for solar cell module 111 in an embodiment. While providing such support, first and second encapsulation layers 30 and 40 may also provide flexibility. Such layers also may allow visible light to pass through to solar cell 50. Encapsulation layers 30 and 40 may also protect substrate 20 from breaking and/or cracking during handling and/or use during field applications, as well as protect solar cell 50 from environmental elements, such as oxidation, moisture, and dirt, for example. Thicknesses of encapsulation layers 30 and 40 may be varied to account for different materials and design criteria, such as desired flexibility, transparency, and environmental ruggedness, just to list a few examples. In one particular embodiment, for example, encapsulation layers 30 and 40 may be several times thicker than substrate 20. Such thicknesses may lead to an ultra-thin glass substrate having a greater flexibility than one or both of encapsulation layers 30 and 40.

FIG. 2 is a cross-sectional view of a solar cell module, according to another embodiment. Solar cell module 212 may include encapsulation layer 32 comprising multiple polymer layers, such as polymer adhesive layer 110 and outer polymer sheet 120. Adhesive layer 110 may include EVA, and polymer sheet 120 may include ETFE, fluoropolymer Tefzel®, or another fluoropolymer. However, these are merely examples of materials that may be used as adhesive layers, and claimed subject matter is not limited in this respect. Encapsulation layer 42 may comprise an adhesive polymer layer 130 such as EVA that encapsulates solar cell 50 and may act as an adhesive to another structural layer or component (not shown). Such structural layers or components may include, for example, roof tile or other construction materials, metal, and/or any material that may physically support solar cell module 212. Encapsulation layer 42 need not include transparent materials since solar cell 50 may receive visible light that passes through transparent polymer adhesive layer 110 and thick outer polymer sheet 120, for example. Of course, the above descriptions of layers included in encapsulation layers 32 and 42 are merely examples, and claimed subject matter is not so limited. Other embodiments may include additional layers or materials as part of encapsulation layers 32 and 42, for example.

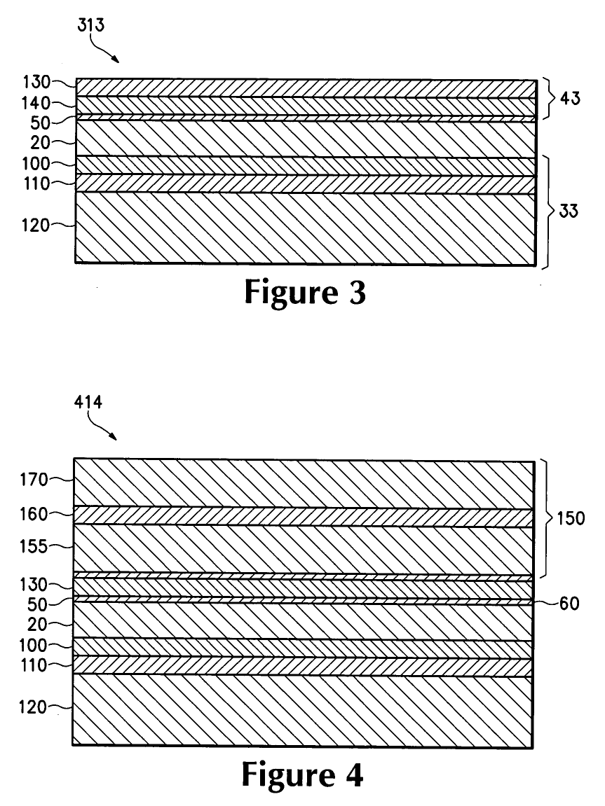

FIG. 3 is a cross-sectional view of a solar cell module 313, according to another embodiment. Solar cell module 313 may include encapsulation layers 33 and 43, each comprising multiple polymer layers as follows. Encapsulation layer 33 may include hard polymer layer 100, which may strengthen substrate 20 by filling any micro-cracks in substrate 20, for example. Hard polymer layer 100 may also create a buffer between substrate 20 and an adhesive layer 110 such as EVA, for example. Adhesive layer 110 may act as an adhesive between hard polymer layer 100 and a thick outer polymer sheet 120, such as ETFE or fluoropolymer Tefzel®, for example. Encapsulation layer 43 may comprise adhesive polymer layer 130 and a hard polymer layer 140 to form a protective buffer between solar cell 50 and adhesive polymer layer 130.

FIG. 4 is a cross-sectional view of a solar cell module, according to another embodiment. Solar cell module 414 may include a structural backing 150 adhered by an adhesive layer 130. Structural backing 150 may include a structural layer 155 such as Mylar, for example, an adhesive layer 160, and an outer polymer sheet 170 such as ETFE or fluoropolymer Tefzel®. In a particular embodiment, structural layer 155 may comprise Mylar coated with aluminum. The relatively high tensile strength of Mylar may provide structural support while its metal layer may provide a moisture barrier.

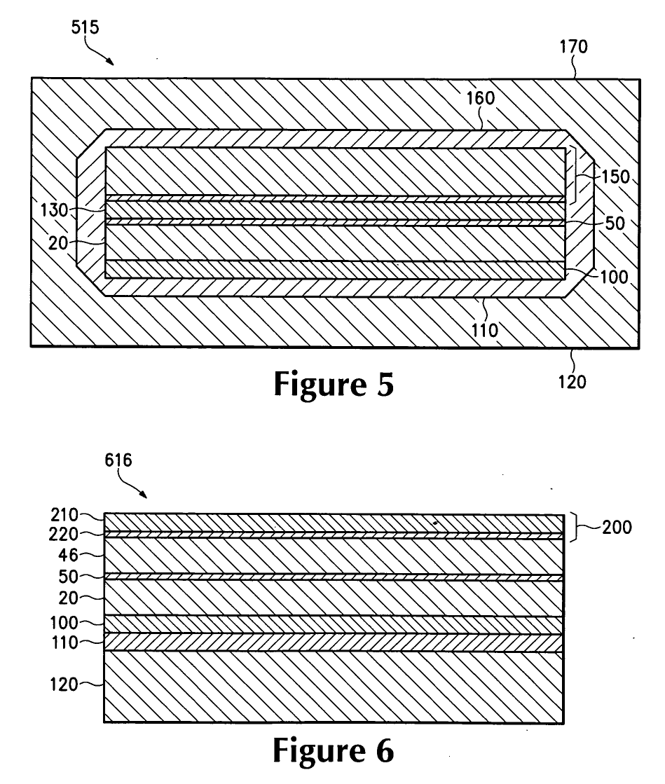

FIG. 5 is a cross-sectional view of a solar cell module, according to another embodiment. Solar cell module 515 may include outermost encapsulation layers 120 and 170 that join beyond the edges of solar cell 50. Solar cell module 515 may also include adhesive layers 110 and 160 that join beyond the edges of solar cell 50. For example, encapsulation layers 120 and 170 may contact and bond to one another outside the edges of substrate 20 to provide a sealant that surrounds and encapsulates substrate 20 and solar cell 50. Such an encapsulation may protect substrate 20 and solar cell layers TCO 60, light absorbing semiconductor layers 70 and 80, and conductive back contact 90 from moisture and other contaminants.

FIG. 6 is a cross-sectional view of a solar cell module, according to another embodiment. Solar cell module 616 may include a layer of porcelain enameled steel 200 that comprises a porcelain layer 220 and a steel foil 210, for example. An encapsulation layer 46 may bond porcelain layer 220 to solar cell 50. Porcelain layer 220 may provide moisture protection for underlying elements, including solar cell 50. In a particular embodiment, steel foil 210 may be an outermost layer to provide additional structural support to solar cell module 61 6 without restricting flexibility of the underlying solar cell 50.

FIG. 7 is a cross-sectional view of a solar cell module, according to another embodiment. Solar cell module 717 may include glass sheets 220 and 230 attached to encapsulation layers 37 and 47, respectively. Such glass sheets may provide moisture protection to solar cell 50 and add structural support to solar cell module 717. In a particular embodiment, either or both glass sheets 220 and 230 may be used as an interface material to integrate solar cell module 717. For example, a bonding material (not shown) may bond glass sheets 220 or 230 to various building materials (not shown), such as roofing tile.

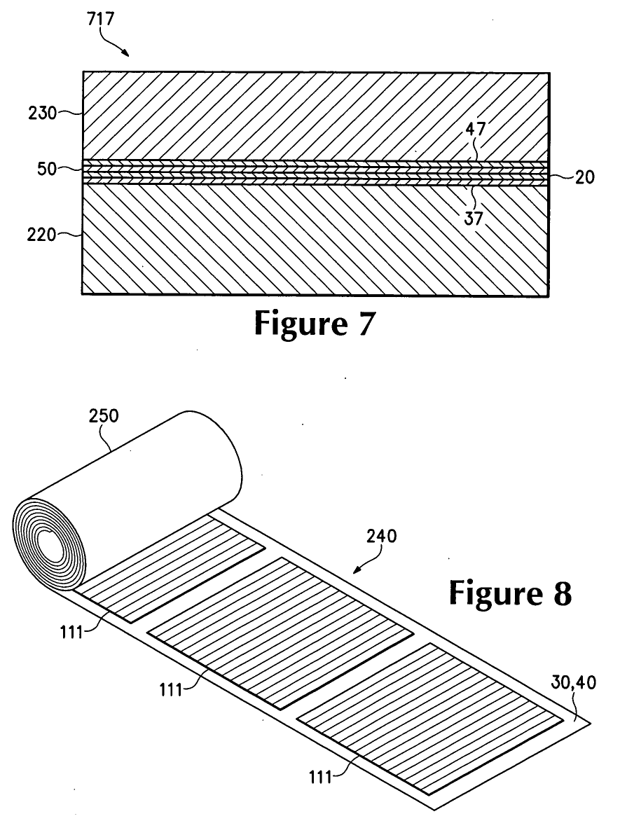

FIG. 8 is a perspective view of a solar module array, according to an embodiment. Solar module array 240, for example, may comprise solar cell modules 111, such as those shown in FIG. 1, which may be electrically interconnected and encapsulated in lamination layers 30 and 40. Solar module array 240 may have a sheet-form and be capable of being rolled into a roll 250 for storage and handling. In a particular example, solar module array 240 is about one meter wide and ten meters long, and capable of a total peak power output of about 1000 watts. However, this is merely an example of dimensions and power output of such a solar module, and claimed subject matter is not limited in this respect.

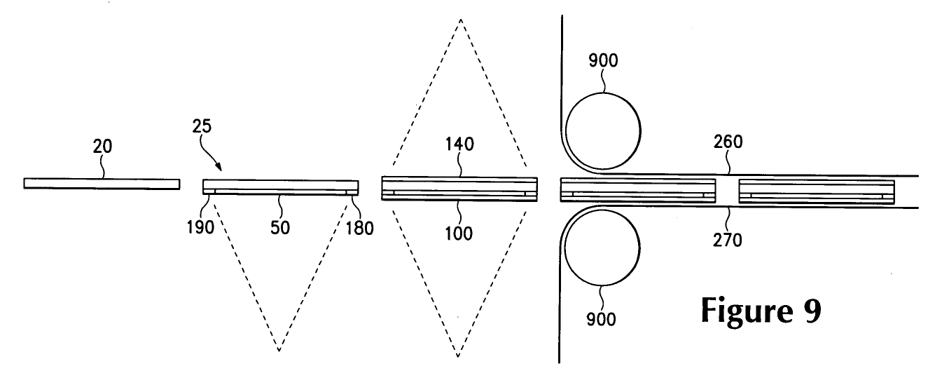

FIG. 9 is a schematic showing a process of manufacturing a solar cell module, such as solar cell module 111, according to an embodiment. Solar cell 50 may be deposited on a substrate 20. In a particular embodiment, solar cell 50 may be formed by depositing TCO as SnO₂:F on substrate 20 using chemical vapor deposition, followed by patterning using a laser scribing system, for example. Light absorbing semiconductor layers, such as layers 70 and 80 shown in FIG. 1, may be sequentially deposited on TCO as CdS and CdTe thin films, respectively, using vapor transport such as close space sublimation, for example. In a particular implementation, during vapor transport, source material may be heated to about 700° C. in a low-pressure environment to create a vapor that contacts a SnO₂:F-coated substrate 20, which is heated to a temperature between about 300 and 600° C. Of course, these temperatures are merely examples, and claimed subject matter is not so limited. After CdS and CdTe thin films are deposited, the thin films may be treated with a CdCl₂ vapor as substrate 20 is heated to a temperature between 300 and 500° C. A patterning of the light absorbing semiconductor layers may be conducted by a laser scribing system, for example. Finally, a conductive back contact, such as back contact 90 shown in FIG. 1, may be deposited on light absorbing semiconductor layer 80 by sputtering or evaporation. A final patterning by a laser scribing system may be applied to the conductive back contact. Thereafter, an exposed side of substrate 20 may be sprayed with liquid polymer, which may then be cured to form hard polymer coating 100. In a particular embodiment, such liquid polymers may also be applied by dipping and/or spin coating. In an optional embodiment, exposed back sides of solar cell 50 and a conductive back contact may be partially masked to cover negative and positive electrodes 180 and 190 and then sprayed with liquid polymer, which is then cured to form hard polymer coatings 100 and 140 on one or both sides of composite solar cell 25. Subsequently, hard polymer coating 140 may be removed from over electrodes 180 and 190, which may provide conductive contacts for the negative and positive ends of solar cell module 111. Electrodes 180 and 190 may be disposed at or near distal ends of solar cell module 111. Such electrodes may remain exposed for future interconnection of multiple solar cell modules. After applying hard polymer coating 100, solar cell modules 111 may be sorted and grouped based on their performance. Solar cell modules with similar performance may be grouped together during a lamination process to form, for example, solar module array 240 shown in FIG. 8. A roll laminator 900 may be used to encapsulate the resulting structure with lamination sheets 260 and 270 in a vacuum environment to ensure that air bubbles, particles, and/or vapors are removed from the structure.

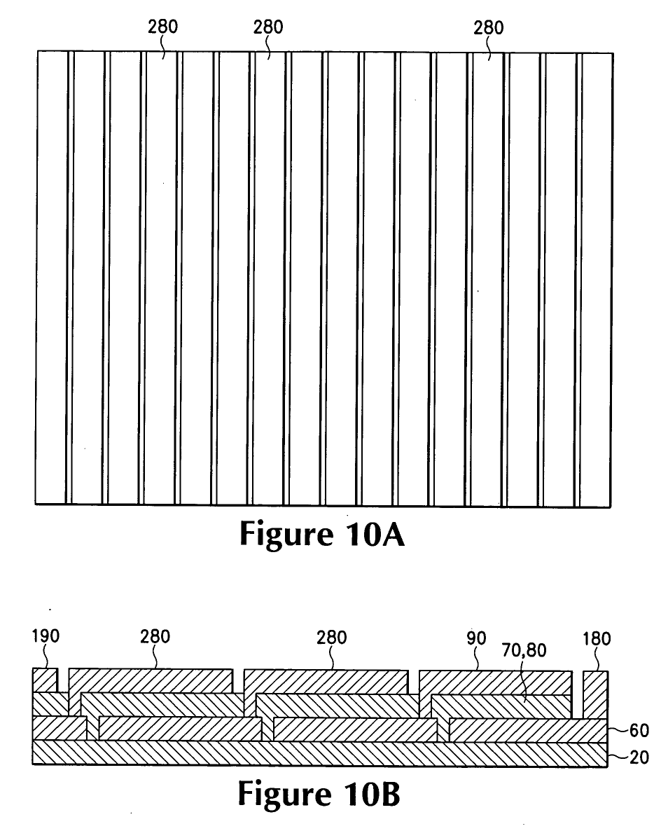

FIG. 10A is a top view and FIG. 10B is a cross-sectional view of a solar cell module, such as solar cell module 111 shown in FIG. 1 that has undergone laser scribing, according to an embodiment. Laser scribing may be applied to TCO layer 60, semiconductor layers 70 and 80, and conductive back contact 90, for example. After such laser scribing, solar cell module 111 may comprise a series of electrically inter-connected solar cells with positive and negative electrodes 180 and 190 situated at right and left ends of the module, as shown in FIG. 10B. In one particular embodiment, solar cell 50 may be patterned into strips 280 that are spaced apart at regular intervals. Such strips may be about 1 to 2 cm wide in a particular implementation. Solar cell 50 may be patterned, for example, into such strips by laser scribing, masking, and/or photo-resistive etching of TCO 60 and light absorbing semiconductor layers 70 and 80 after these elements are sequentially deposited as stacked layers.

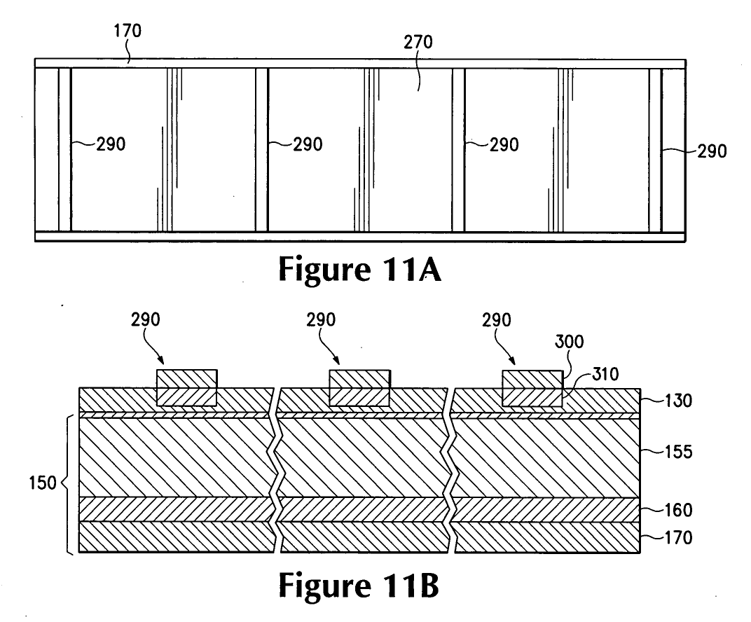

FIG. 11A is a top view and FIG. 11B is a cross-sectional view of a lamination sheet 270, according to an embodiment. Such a lamination sheet may be applied to a solar cell module as in the process shown in FIG. 9, for example. Lamination sheet 270 may include strips of conductive material 290 to interconnect solar cell modules 111 subsequent to laying the lamination sheet onto the solar cell modules. Conductive strips 290, which may be employed as electrical contacts for electrodes 180 and 190 shown in FIG. 10B for example, may comprise layers of copper 300 and solder paste 310. In a particular embodiment, conductive strips 290 may be bonded to lamination sheet 270 by adhesive layer 130. As described above regarding an embodiment shown in FIG. 4, a structural backing 150, upon which adhesive layer 130 may be placed, may include a structural layer 155, an adhesive layer 160, and an outer encapsulation sheet 170. As shown in the top view of FIG. 11A, outer encapsulation sheet 170 may project beyond lamination sheet 270 to provide a contact surface to bond to a corresponding contact surface of an adjacent lamination sheet 270, according to a particular implementation.

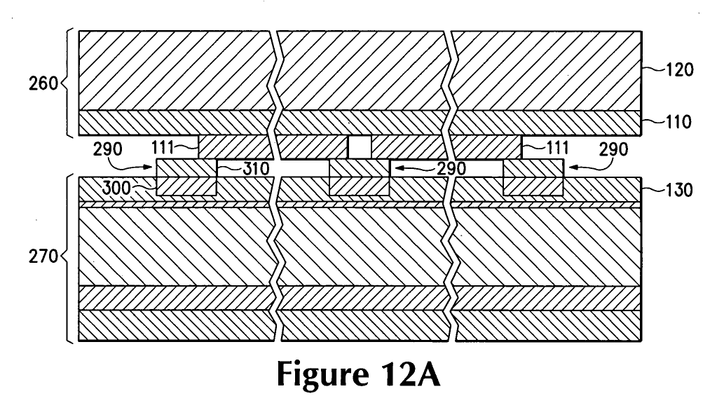

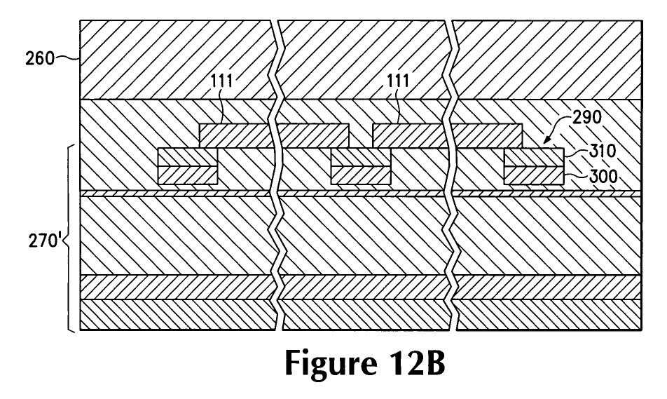

FIGS. 12A and 12B are cross-sectional views of solar cell modules 111 sandwiched between lamination layers 260 and 270, according to an embodiment. In FIG. 12A, multiple solar cell modules 111 are aligned with, and interconnected by, conductive strips 290. In a process leading from FIG. 12A to FIG. 12B, lamination layers 260 and 270 may be heated and compressed to fuse adhesive layers 110 and 130 to solar cell module 111. During heating, solder paste 310 may flow to connect solar cell modules 111 to conductive strips 290, thereby forming electrically interconnected solar cell modules 111. Modified lamination layer 270 may comprise lamination layer 270 subsequent to such heating. In a particular embodiment, such interconnected solar cell modules may be encapsulated by outer encapsulation layer 170 (FIG. 11A) that may extend beyond an edge of lamination sheet 270 to contact a matching outer polymer layer 120 of lamination sheet 260.

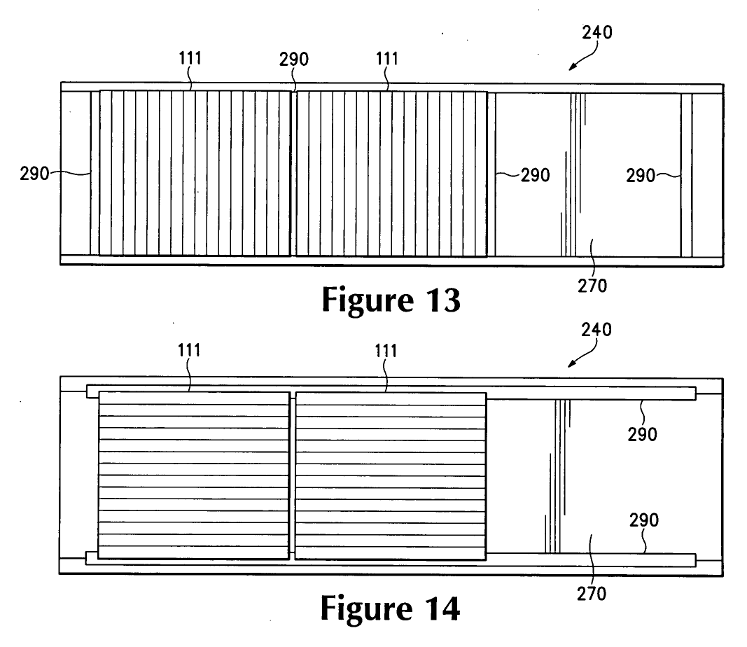

FIGS. 13 and 14 are top views showing solar module arrays 240 comprising two adjacent solar cell modules, such as solar cell modules 111 shown in FIG. 1, according to an embodiment. FIG. 13 shows an embodiment wherein solar cell modules 111 are connected in series. FIG. 14 shows an embodiment wherein solar cell modules 111 are connected in parallel. In either embodiment, conductive strips 290 may be used to interconnect the multiple solar cell modules.

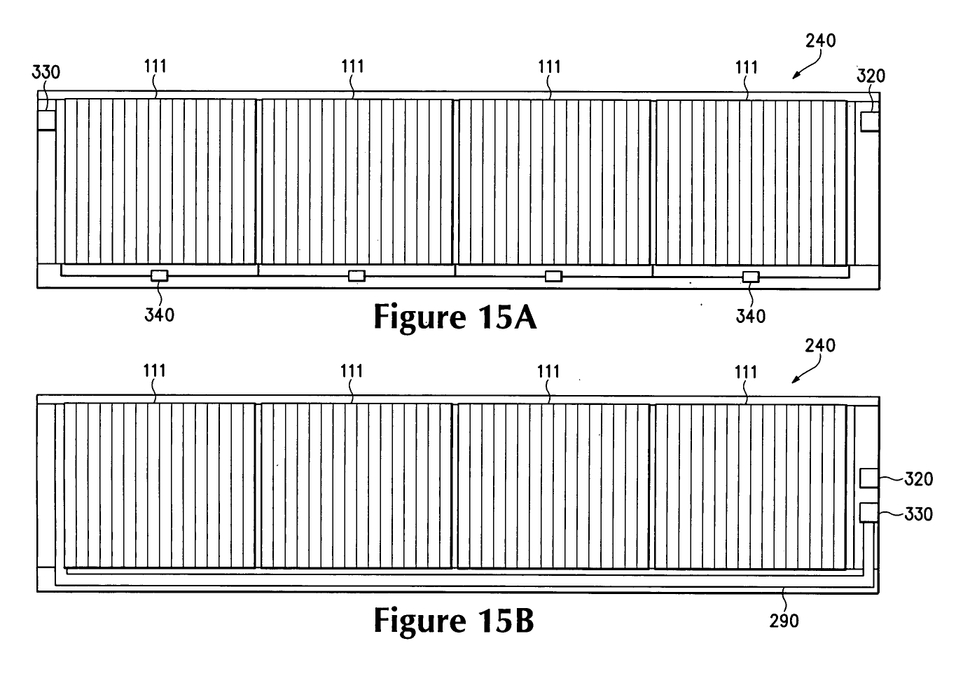

FIGS. 15A and 15B are top views showing embodiments of a solar module array. Solar module array 240 may comprise multiple solar cell modules 111 connected in series, as shown in FIG. 13, for example. In the embodiment of FIG. 15A, junctions 320 and 330 may be disposed at ends of solar module array 240. Referring to FIG. 10, junction 320 may correspond to electrode 180, for example, while junction 330 may correspond to electrode 190. In a particular embodiment, by-pass diodes 340 may be linked electrically in parallel with each solar cell module 111 to prevent hot spots during partial solar shading, for example. In the embodiment of FIG. 15B, junctions 320 and 330 may be on the same end of solar module array 240, and conductive strip 290 may extend from junction box 330.

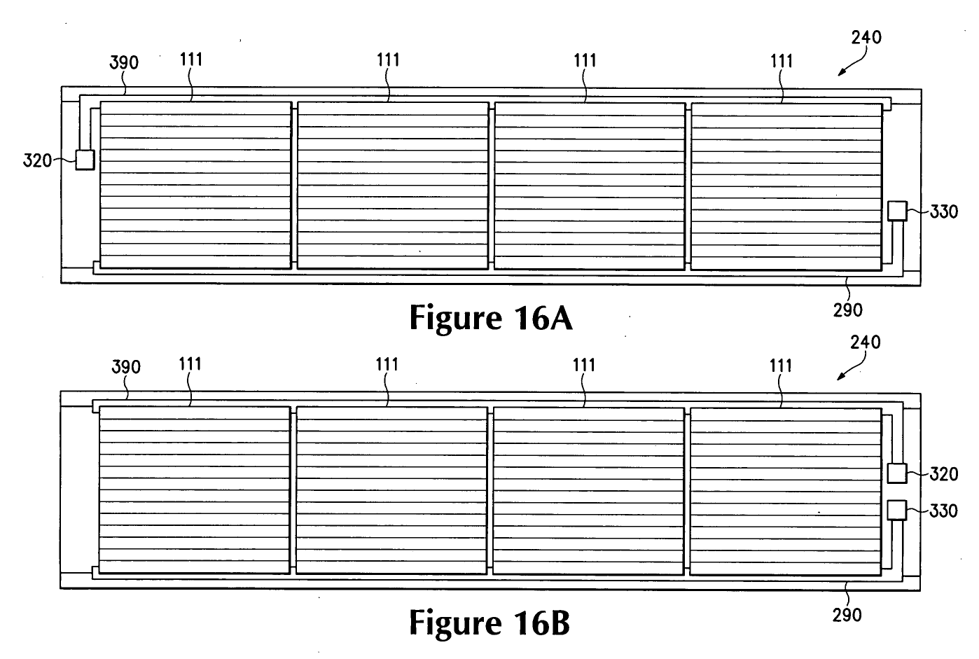

FIGS. 16A and 16B show two embodiments of a solar module array including solar cell modules 111 connected in parallel, such as solar module array 240 shown in FIGS. 8 and 14, for example. In the embodiment of FIG. 16A, junctions 320 and 330 may be disposed at ends of solar module array 240. Junction 320 may correspond to electrode 180 of the leftmost solar cell module 111 in solar module array 240, for example, while junction 330 may correspond to electrode 190 of the rightmost solar cell module 111 in solar module array 240. By-pass diodes 340 may be linked electrically in parallel with individual solar cell module 111 to prevent hot spots during partial solar shading, for example. In the embodiment of FIG. 15B, junctions 320 and 330 may be disposed on the same end of solar module array 240, and conductive strip 290 may extend from junction box 330.

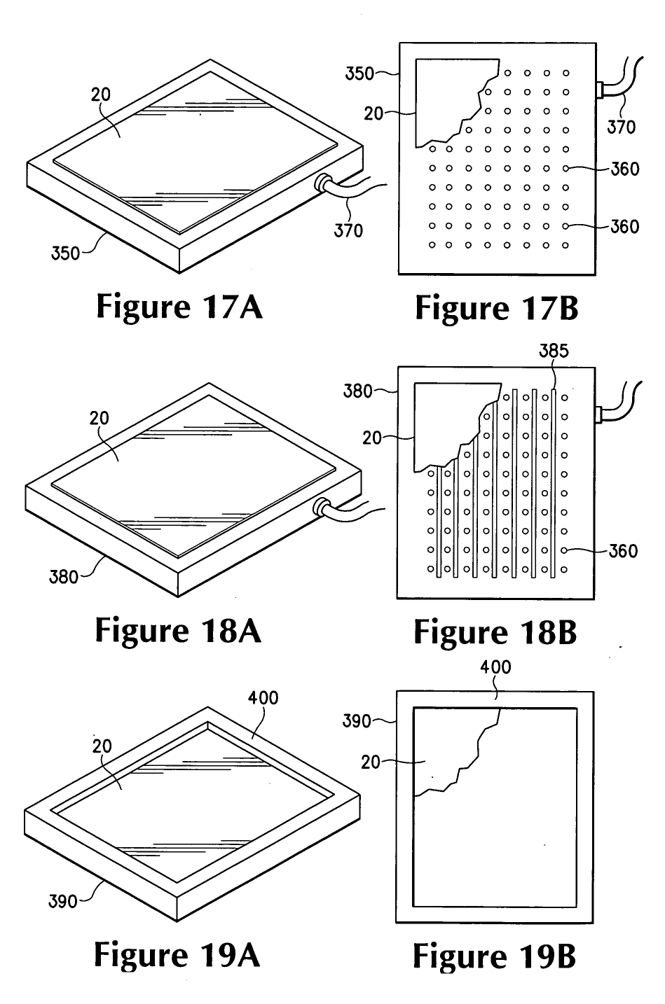

FIGS. 17A and 17B show a substrate handler 350, according to an embodiment. Such a substrate handler may be adapted to handle ultra-thin material, such as ultra-thin glass, which may be used as a substrate for solar cell 50, as shown in FIG. 1 for example. Low pressure such as a vacuum in holes 360 may provide suction to hold substrate 20 to substrate handler 350. Holes 360 may be evenly distributed across the substrate surface. Though a sufficient vacuum may be enough to hold the weight of an inverted glass substrate, for example, pressure in holes 360 may be controlled to prevent breakage of such a glass substrate. Flexible hose 370 may be attached to substrate handler 350 to enable its movement while maintaining suction. In one embodiment, to prevent inadvertent deposition of materials on substrate handler 350 during processing, a mask (not shown) may be used over substrate 20 to limit a deposition area. In an alternative embodiment, substrate 20 may be slightly larger than substrate handler 350 with edges of substrate 20 extending beyond substrate handler 350 so that substrate handler 350 may be completely covered from the deposition materials. In another alternative embodiment, a substrate handler 380, shown in FIGS. 18A and top view 18B, may include evenly-spaced slits 385 to allow laser scribing through the slits.

FIGS. 19A and 19B show a substrate handler, according to another embodiment. Substrate handler 390 may be used during deposition or laser scribing. Substrate handler 390 may comprise a sheet of relatively thick glass or other material such as a polymer, metal, or ceramic with a peripheral raised edge 400. Such a thick material may be substantially more rigid than a flexible substrate. In a particular embodiment, a sheet of relatively thick glass may comprise the same glass material that may be used as an ultra-thin, flexible substrate for substrate 20, for example. During a process of deposition or laser scribing, such a substrate may be laid on top of substrate handler 390 so that it fits securely within raised edge 40.

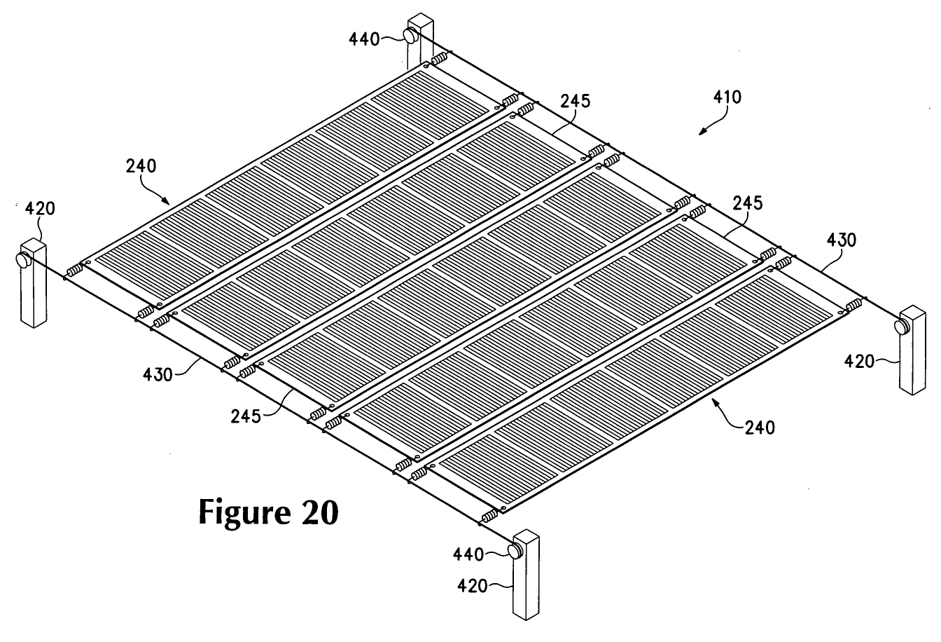

FIG. 20 is a perspective view of an embodiment of a cable and post mounting system 410 that includes solar module arrays, such as solar module arrays 240 shown in FIG. 8. Solar module arrays may be configured in a solar panel 245, of which one or more may use such a mounting system. In a particular example, mounting system 410 may include posts 420 and cables 430 that are strung tightly between the posts by adjustment cranks 440. Solar module arrays 240 may be suspended between cables 430. Cables 430 may serve both as a support structure and an electrical cable to bring power generated from solar module arrays 240 to a junction point (not shown).

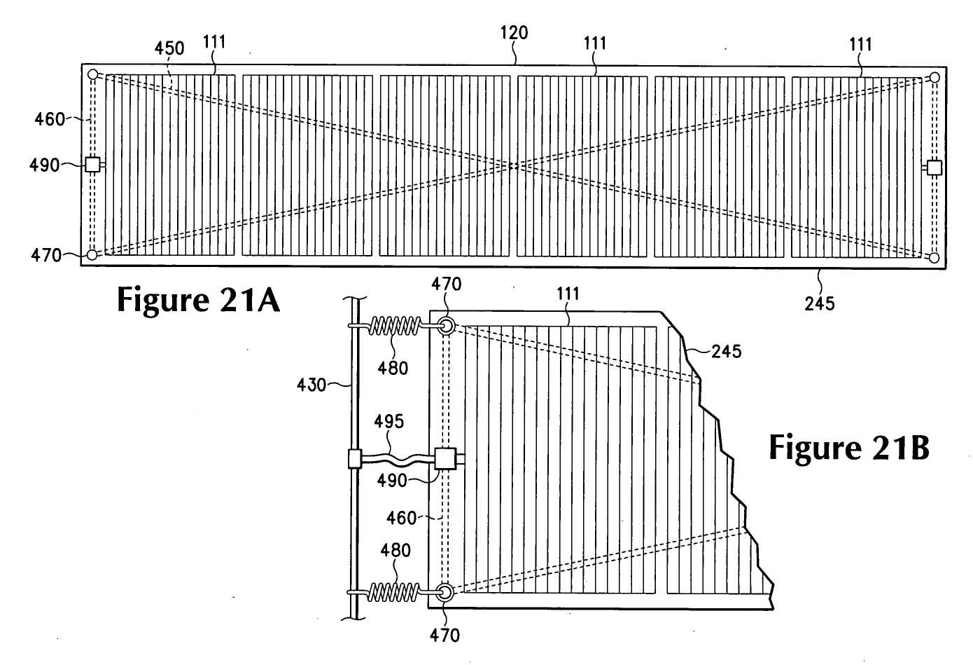

FIG. 21A is a top view of a solar panel 245 included in cable and post mounting structure 410, according to an embodiment. FIG. 21B is a close-up view of an end region of solar panel 245. Solar panel 245, for example, may be reinforced structurally with a wire truss 450 and rigid end bars 460. Wire truss 450 and rigid end bars 460 may intersect at rings 470. A spring-loaded connector 480 may be used to link rings 470 to cable 430. Cable 430 may also act as an electrical conduit to interconnect solar panels 245 to the mounting system. A junction box 490 may be connected to an interconnect point on cable 430 with a patch cable 495, for example.

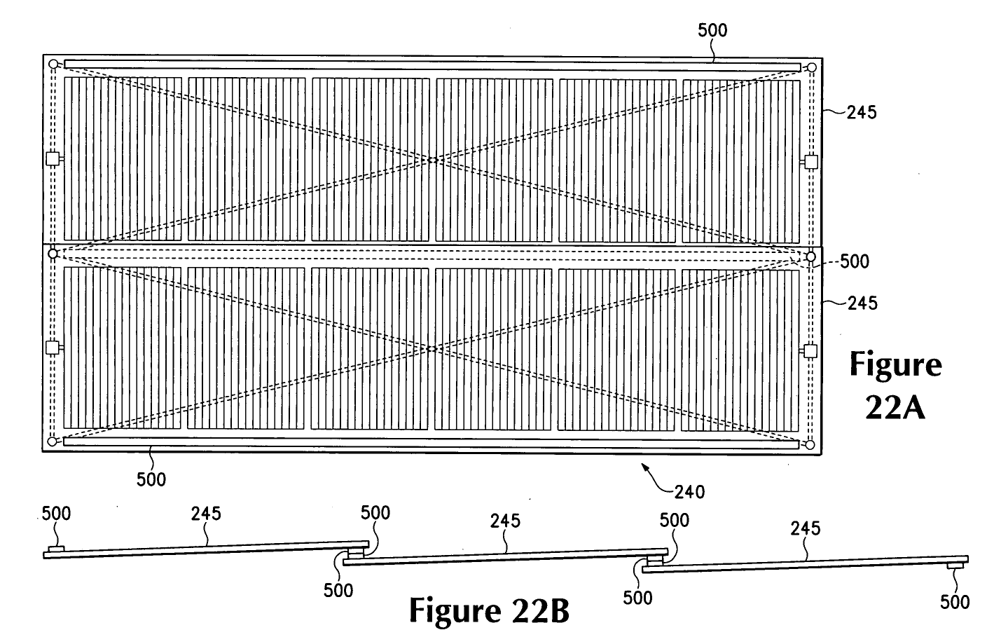

FIG. 22A is a top view of two solar panels 245 that may be interconnected using panel connectors 500, as shown in a detail view of FIG. 22B, according to an embodiment. Such connectors may include Velcro strips attached along sides of solar panels 245, snap connectors, and/or nuts and bolts, just to name a few examples. FIG. 22B is a cross-sectional view, for example, of three such solar panels 245 configured to be mechanically connected by Velcro strips.

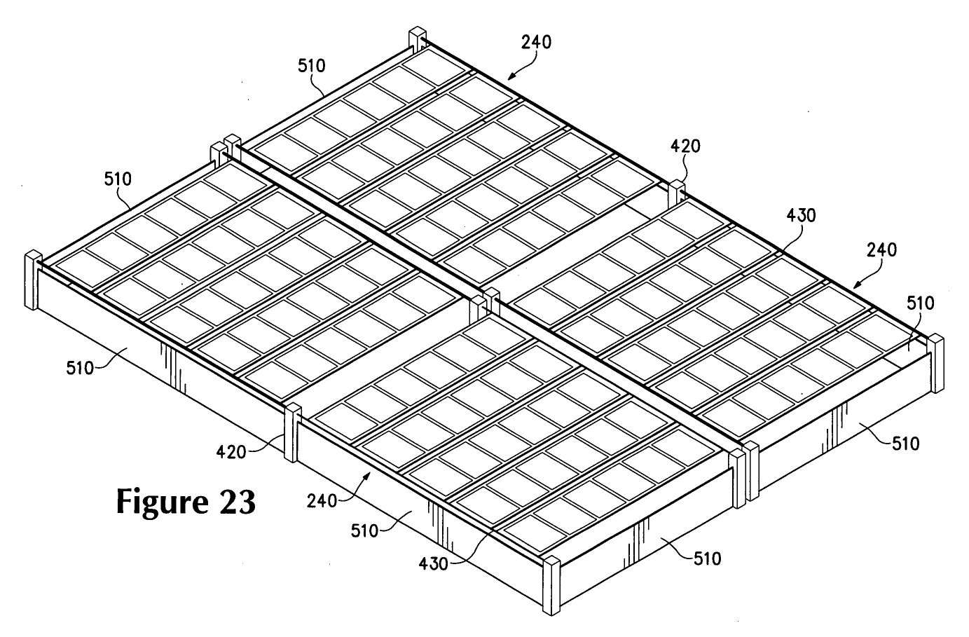

FIG. 23 is a perspective view of an array of multiple cable and post mounting systems 410, according to an embodiment. Wind blockers 510 may be attached to outer edges of the array to provide protection from lift forces from wind gusts.

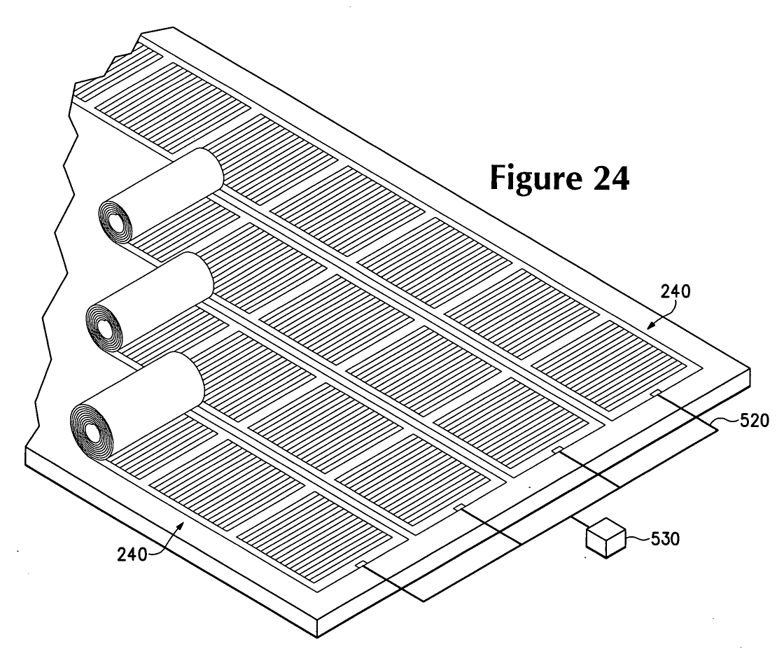

FIG. 24 is a perspective view of an installation of solar module arrays 240, according to an embodiment. Such an installation may be on a flat roof top or surface. In this configuration, solar module array 240 may be rolled out substantially flat and stapled or glued to the surface. Solar module arrays 240 may be electrically interconnected by cables 520 to junction box 530.

Accordingly, a solar cell module, consistent with the embodiments described herein, may be flexible and light weight, and well-suited to be mounted on and physically conform to various structures such as curved glass on a roof. This facilitates handling and installation on a wide variety of surfaces. Encapsulation layers such as encapsulation layers 30 and 40 shown in FIG. 1 may also provide a hermetic seal that is not prone to delamination when solar cell module 1 is bent and flexed, for example. Additionally, hard polymer 100 may act as a strength enhancer by forming “bridge bonds” that may heal relatively small flaws on the surface of the substrate. Substrate strength may thus be enhanced, static fatigue reduced, and tighter bend ability achieved.

Also as described above, embodiments may include encapsulation layers that may include a polymer, which need not be exposed to relatively high temperatures which may be used to deposit solar cell 50 on substrate 20. Such temperatures may damage the structural integrity of polymer layers. Instead, solar cell 50 may be deposited on substrate 20 at a relatively high temperature of at least 300° C., and then encapsulation layers such as encapsulation layers 30 and 40 shown in FIG. 1 may be deposited on substrate 20 and solar cell 50 at a relative low temperature below 300° C. Thus, encapsulation layers need not be exposed to the relatively high temperature at any time during manufacture or operation.

In addition, substrate 20 may be fed horizontally or vertically through deposition chambers or stations in a process line to form solar cell 50 and then encapsulation layers 30 and 40, as shown in FIG. 1 for example. Substrate 20 may be fed on a substrate handler (such as substrate handler 350, 380 or 390) that may easily be incorporated in an existing solar cell module manufacturing line designed for thick sheet glass substrates.

While there has been illustrated and described what are presently considered to be example features, it will be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular examples disclosed, but that such claimed subject matter may also include all aspects falling within the scope of appended claims, and equivalents thereof.

What is claimed is:

1. A solar cell apparatus comprising:
a solar cell including a thin film solar cell disposed on a flexible and substantially transparent substrate.

2. The solar cell apparatus of claim 1, further comprising:
a first encapsulation layer disposed on said flexible and substantially transparent substrate; and
a second encapsulation layer disposed on a second side of said solar cell.

3. The solar cell apparatus of claim 1, wherein said flexible and substantially transparent substrate includes an ultra-thin glass substrate.

4. The solar cell apparatus of claim 2, wherein each of said first and second encapsulation layers are thicker than said flexible and substantially transparent substrate.

5. The solar cell apparatus of claim 3, wherein said ultra-thin glass substrate has a greater flexibility than that of said first and second encapsulation layers.

6. The solar cell apparatus of claim 1, wherein said flexible and substantially transparent substrate has a thickness substantially equal to or less than 200 micrometers.

7. The solar cell apparatus of claim 2, wherein said first encapsulation layer is substantially transparent and said second encapsulation layer is opaque.

8. The solar cell apparatus of claim 2, wherein said second encapsulation layer includes, an adhesive layer.

9. The solar cell apparatus of claim 8, wherein said second encapsulation layer includes a thin hard polymer layer and an outer fluoropolymer layer.

10. The solar cell apparatus of claim 3, wherein said ultra-thin glass substrate includes fused glass particles.

11. The solar cell apparatus of claim 3, wherein said ultra-thin glass substrate includes borosilicate glass.

12. The solar cell apparatus of claim 1, wherein said thin film solar cell is capable of being exposed to light passing through said flexible and substantially transparent substrate.

13. A method comprising:
depositing a thin film solar cell onto a flexible and substantially transparent substrate to produce a solar cell.

14. The method of claim 13, further comprising:
encapsulating said solar cell with one or more encapsulation sheets to provide structural support and environmental protection to said solar cell.

15. The method of claim 13, wherein said flexible and substantially transparent substrate includes an ultra-thin glass substrate.

16. The method of claim 14, wherein said one or more encapsulation sheets include multiple conductors to contact said solar cell.

17. The method of claim 16, further comprising:
connecting said multiple conductors to said solar cell; and
bonding said solar cell to said one or more polymer sheets.

18. The method of claim 15, further comprising:
filling in voids or cracks in said ultra-thin glass substrate using a silica coating.

19. The method of claim 15, further comprising:
filling in voids or cracks in said ultra-thin glass substrate using a hard polymer or silica coating.

20. The method of claim 14, wherein each of said one or more encapsulation sheets are thicker than said flexible and substantially transparent substrate.

21. The method of claim 14, wherein said flexible and substantially transparent substrate has a greater flexibility than that of said one or more encapsulation sheets.

22. The method of claim 14, wherein at least one of said encapsulation sheets is substantially transparent and at least one of said encapsulation sheets is opaque.

23. The method of claim 14, wherein at least one of said encapsulation sheets includes an adhesive layer.

24. The method of claim 13, wherein said flexible and substantially transparent substrate has a thickness substantially equal to or less than 200 micrometers.

25. The method of claim 15, wherein said ultra-thin glass substrate includes borosilicate glass.

26. The method of claim 15, further comprising forming said ultra-thin glass substrate by fusing borosilicate powder.

27. The method of claim 13, further comprising:
applying a liquid polymer to said flexible and substantially transparent substrate to form a hard polymer coating.

28. The method of claim 27, wherein said applying comprises:
spraying said liquid polymer; and
curing said liquid polymer to form said hard polymer coating.

29. The method of claim 27, wherein said applying comprises:
dipping and/or spin coating said flexible and substantially transparent substrate to apply said liquid polymer; and
curing said liquid polymer to form said hard polymer coating.

30. The method of claim 13, further comprising:
laying said flexible and substantially transparent substrate onto a substrate handler during said depositing, wherein said flexible and substantially transparent substrate comprises a material of a first thickness and said substrate handler comprises said material of a second thickness that is substantially greater than said first thickness.

31. The method of claim 30, wherein said material comprises glass.

32. The method of claim 13, further comprising:
after depositing said thin film solar cell onto said flexible and substantially transparent substrate, depositing a polymer onto said solar cell.

33. The method of claim 13, further comprising:
after depositing said thin film solar cell onto said flexible and substantially transparent substrate, laminating a multiple layer polymer sheet onto said solar cell.

34. Apparatus with the inventive feature as shown and described.

35. Methods with the inventive feature as shown and described.
